(19) United States
(12) Patent Application Publication
(10) Pub. No.: US 2025/0341481 A1
(43) Pub. Date: Nov. 6, 2025

(54) NON-DESTRUCTIVE SURFACE METROLOGY OF PATTERNED WAFERS

(71) Applicant: Applied Materials Israel Ltd., Rehovot (IL)

(72) Inventors: Itamar Shani, Mishmar David (IL); Konstantin Chirko, Rehovot (IL); Lior Yaron, Ness Ziona (IL); Ching-Hung Lai, Hsinchu (TW); Albert Karabekov, Rehovot (IL); Guy Eytan, Kfar-Aviv (IL); Ofir Vadasz, Nofech (IL)

(73) Assignee: Applied Materials Israel Ltd., Rehovot (IL)

(21) Appl. No.: 18/656,317

(22) Filed: May 6, 2024

(51) Int. Cl. G01N 23/203

(52) U.S. Cl. CPC G01N 23/203; G01N 2223/401; G01N 2223/418; G01N 2223/6116

(57) ABSTRACT

Disclosed herein is a non-destructive method for determining a vertical extent of a feature of a patterned wafer, the method including using a scanning electron microscope (SEM) to scan an e-beam over a featured region on a tested wafer and sense backscattered electrons returned from the tested wafer to obtain a backscattered electron (BSE) image of the featured region, wherein the scanned e-beam is projected on the tested wafer so as to impinge thereon at an electronic tilt angle of up to 2° in order to minimize non-linear diffraction effects.

### TECHNICAL FIELD

The present disclosure relates generally to non-destructive surface metrology of patterned wafers.

### BACKGROUND OF THE INVENTION

A key challenge in process control of patterned wafers is three-dimensional surface metrology; that is, the mapping of the topography of structures on a surface of a patterned wafer. With the shrinking of design rules, this task grows ever more complex as increasingly greater precision is required. Ideally, the increase in precision should not come at the expense of throughput. State-of-the-art techniques for three-dimensional surface metrology of patterned wafers include optical-based techniques, scanning electron microscopy-based techniques, transmission electron microscopy-based techniques, and atomic force microscopy-based techniques.

### BRIEF SUMMARY OF THE INVENTION

Aspects of the disclosure, according to some embodiments thereof, to non-destructive surface metrology of patterned wafers. More specifically, but not exclusively, aspects of the disclosure, according to some embodiments thereof, relate to non-destructive height estimation of vertically extending features on the surface of a patterned wafer based on measurement of backscattered electrons.

Thus, according to an aspect of some embodiments, there is provided a non-destructive method for determining a vertical extent of a feature of a patterned wafer, the method including: using a scanning electron microscope (SEM) to scan an e-beam over a featured region on a tested wafer and sense backscattered electrons returned from the tested wafer to obtain a backscattered electron (BSE) image of the featured region, wherein the featured region includes at least one vertically-extended feature, which is (i) characterized by a BSE yield per unit volume that is substantially uniform along the vertical direction and/or (ii) depressed and delimited on sides thereof by a material characterized by a BSE yield per unit depth and/or unit volume that is substantially uniform along the vertical direction, wherein the scanned e-beam is projected on the tested wafer so as to impinge thereon at an electronic tilt angle of up to 2° in order to minimize non-linear diffraction effects; and for each of the at least one feature: computing a respective quantity C indicative of a contrast associated with the feature in the obtained BSE image using grey-level values pertaining to the feature and at least one adjacent area to the feature; and computing a respective quantity h, which is indicative of a vertical extent of the feature, based on C and a value of a landing energy of the scanned e-beam.

According to some embodiments, h is computed based on a normalized contrast C [symbol] and the value of the landing energy of the scanned e-beam, wherein C [symbol] is obtained from C through normalization by a reference BSE yield at the landing energy, or a quantity indicative thereof.

According to some embodiments, the reference BSE yield is an unpatterned wafer BSE yield corresponding to an intensity of backscattered electrons, which would be returned from an unpatterned region of the tested wafer near the featured region.

According to some embodiments, C is the contrast associated with the feature in the obtained BSE image and/or wherein h is the vertical extent of the feature.

According to some embodiments, the at least one feature includes a plurality of features, the features are of a same intended design and are nominally arranged in a periodic array.

According to some embodiments, the landing energy is selected such that a diameter of a bulb-shaped interaction region, which is formed by the scanned e-beam within the tested wafer and wherefrom substantially all of the sensed backscattered electrons are returned, is greater than a pitch, or each of the pitches, of the periodic array by a factor of at least about 10.

According to some embodiments, the landing energy is selected such that a diameter of a bulb-shaped interaction region, which is formed by the scanned e-beam within the tested wafer and wherefrom substantially all of the sensed backscattered electrons are returned, is greater than the vertical extent of the feature by a factor of at least about 10.

According to some embodiments, the landing energy is selected such that the scanned e-beam penetrates the tested wafer to a depth which is greater than the vertical extent of the feature by a factor of at least about 10.

According to some embodiments, the scanned e-beam is projected on the tested wafer so as to impinge thereon about perpendicularly thereto.

According to some embodiments, the scanned e-beam is projected on the tested wafer so as to impinge thereon at an electronic tilt angle of about 1-2° in order to minimize non-linear diffraction effects.

According to some embodiments, the landing energy is selected such that a diameter of a bulb-shaped interaction region, which is formed by the scanned e-beam within the bulk and wherefrom substantially all of the sensed backscattered electrons are returned, is greater by a factor of at least about 10 than periodicity lengths characterizing the bulk and any periodic layers disposed thereon.

According to some embodiments, the method further includes estimating the reference BSE yield of the tested wafer by measuring an intensity of backscattered electrons returned from an unpatterned wafer of a same design intent as the bulk of the tested wafer.

According to some embodiments, the tested wafer is constituted by an unfinished wafer in one of intermediate stages of fabrication thereof following the patterning.

According to some embodiments, the feature is constituted by a fin or a trench of a gate all around (GAA) transistor or a fin field effect transistor (FinFET), in a non-final fabrication stage thereof.

According to some embodiments, the landing energy is between about 10 keV and about 100 keV.

According to some embodiments, the feature is constituted by a fin, the at least one adjacent area is constituted by at least one trench, respectively, which is adjacent to the fin.

According to some embodiments, the tested wafer includes a plurality of the feature; wherein using the SEM is implemented with respect to each of the plurality of the feature; and wherein C corresponds to an average contrast associated with the features in the obtained BSE images and is computed using grey-level values pertaining to each of the features in each of the obtained BSE images, and/or wherein h corresponds to an average vertical extent of the features and is computed using at least C and/or the grey-level values pertaining to each of the features in each of the obtained BSE images, as well as the value of the landing energy of the scanned e-beam and a reference BSE yield at the landing energy or a quantity indicative thereof.

According to an aspect of some embodiments, there is provided a non-transitory computer-readable storage medium. The storage medium stores instructions that cause a system for non-destructive surface metrology of patterned wafers, such as the above-described system, to implement the above-described method with respect to a patterned wafer.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

Unless specifically stated otherwise, as apparent from the disclosure, it is appreciated that, according to some embodiments, terms such as “processing”, “computing”, “calculating”, “determining”, “estimating”, “assessing”, “gauging” or the like, may refer to the action and/or processes of a computer or computing system, or similar electronic computing device, that manipulate and/or transform data, represented as physical (e.g. electronic) quantities within the computing system's registers and/or memories, into other data similarly represented as physical quantities within the computing system's memories, registers or other such information storage, transmission or display devices.

Embodiments of the present disclosure may include apparatuses for performing the operations herein. The apparatuses may be specially constructed for the desired purposes or may include a general-purpose computer(s) selectively activated or reconfigured by a computer program stored in the computer. Such a computer program may be stored in a computer readable storage medium, such as, but not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, flash memories, solid state drives (SSDs), or any other type of media suitable for storing electronic instructions, and capable of being coupled to a computer system bus.

The processes and displays presented herein are not inherently related to any particular computer or other apparatus. Various general-purpose systems may be used with programs in accordance with the teachings herein, or it may prove convenient to construct a more specialized apparatus to perform the desired method(s). The desired structure(s) for a variety of these systems appear from the description below. In addition, embodiments of the present disclosure are not described with reference to any particular programming language. It will be appreciated that a variety of programming languages may be used to implement the teachings of the present disclosure as described herein.

Aspects of the disclosure may be described in the general context of computer-executable instructions, such as program modules, being executed by a computer. Generally, program modules include routines, programs, objects, components, data structures, and so forth, which perform particular tasks or implement particular abstract data types. Disclosed embodiments may also be practiced in distributed computing environments where tasks are performed by remote processing devices that are linked through a communications network. In a distributed computing environment, program modules may be located in both local and remote computer storage media including memory storage devices.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 presents a flowchart of a non-destructive method for surface metrology of patterned wafers based on measurement of backscattered electrons, according to some embodiments;

FIG. 2A schematically depicts a fins-including featured region of a patterned wafer being impinged with an e-beam in accordance with the method of FIG. 1, according to some embodiments;

FIG. 2B presents a close-up view of the featured region of FIG. 2A, according to some embodiments;

FIG. 2C schematically depicts the featured region of FIG. 2A being impinged with an e-beam in accordance with the method of FIG. 1, according to some embodiments;

FIG. 2D presents a perspective of the featured region of FIG. 2A, according to some embodiments;

FIG. 2E schematically depicts a BSE image of the featured region of FIG. 2A, obtained in accordance with the method of FIG. 1, according to some embodiments;

FIG. 3A schematically depicts a featured region of a patterned wafer, according to some embodiments;

FIG. 3B schematically depicts a BSE image of the featured region of FIG. 3A, obtained in accordance with the method of FIG. 1, according to some embodiments;

FIG. 4A schematically depicts a trench-including featured region of a patterned wafer, according to some embodiments;

FIG. 4B schematically depicts a BSE image of the featured region of FIG. 4A, obtained in accordance with the method of FIG. 1, according to some embodiments;

FIG. 5A schematically depicts a projection-including featured region of a patterned wafer, according to some embodiments;

FIG. 5B schematically depicts a BSE image of the featured region of FIG. 5A, obtained in accordance with the method of FIG. 1, according to some embodiments;

FIG. 6A schematically depicts a fins-including featured region of a patterned wafer, according to some embodiments;

FIG. 6B schematically depicts a BSE image of the featured region of FIG. 6A, obtained in accordance with the method of FIG. 1, according to some embodiments;

FIG. 7 schematically depicts a fins-including featured region of a patterned wafer, according to some embodiments;

FIG. 8 schematically depicts a backscattered electron microscopy-based system for surface metrology of patterned wafers, according to some embodiments;

FIG. 9A is a transmission electron microscopy (TEM) image of a silicon structure including a plurality of fins with STI layers there between, according to some embodiments;

FIG. 9B demonstrates the depth (provided by OCD) per silicon structure (such as the silicon structure of FIG. 9A) vs. the BSE contrast at tilt angle of 0, according to some embodiments; and

FIG. 9C demonstrates the depth (provided by OCD) per silicon structure (such as the silicon structure of FIG. 9A) vs. the BSE contrast at tilt angle of 2°, according to some embodiments.

### DETAILED DESCRIPTION OF THE INVENTION

The principles, uses, and implementations of the teachings herein may be better understood with reference to the accompanying description and figures. Upon perusal of the description and figures present herein, one skilled in the art will be able to implement the teachings herein without undue effort or experimentation. In the figures, same reference numerals refer to same parts throughout.

The present disclosure is directed at the determination of the vertical extents of one or more surface features on a wafer, e.g. the determination of the heights of fins in an array of fins. Standard scanning electron microscopy-based techniques utilized to this end, are based on the imaging of secondary electrons (SE). The disclosed techniques, according to some embodiments thereof, are reliant solely on the imaging of backscattered electrons.

Small electronic tilt imaging is prone to errors in estimating topo points positions. This error in lateral positioning of topo points is multiplied by roughly ×10 when estimating height. Another method to measure height variation for trenches is by measuring SE signal from trench bottom. The signal then depends on the aspect ratio of trench depth to its width. Thus, this measurement is non-local and depends on the coupling of multiple geometric parameters, instead of being a direct measurement of height alone.

Advantageously, the herein disclosed method allows measuring a vertical extent (height or depth) of features using SEM with no or small electronic tilt.

An additional advantage of the disclosed technology is that the determination of the vertical extent of a feature requires the acquisition of a single image. This stands in contrast to methods based on the sensing of secondary electrons (SE), wherein typically two images at two different e-beam tilt angles, respectively, must be acquired.

As used herein, the acronyms “SEM” and “BSE” stand for “scanning electron microscope” and “backscattered electron”, respectively. “E-beam” stands for “electron beam”. The term “BSE image” refers to an image obtained by sensing backscattered electrons.

To render the description clearer, throughout the description, certain symbols are used exclusively to label specific types of parameters and/or quantities. g is used to denote a grey-level value. h is used to denote the vertical extent (e.g. height) of a feature. w is used to denote the width of a feature. w′ is used to denote the width of a feature in a BSE and/or SE image of a featured region including the feature.

The symbols g, h, w, and w′ should not be considered as being tied to a specific embodiment with respect to which they are first introduced in the text. Thus, for example, in the context of a first embodiment, a “grey-level value g” and a “height h”, pertaining to a first feature, may be introduced. Later, in the context of a second embodiment, a “grey-level value g” and a “height h”, pertaining to a second feature, may be introduced. However, unless otherwise specified or implied, no properties of the first feature should be assumed carrying over to the second feature due to the use of same symbols.

### Methods

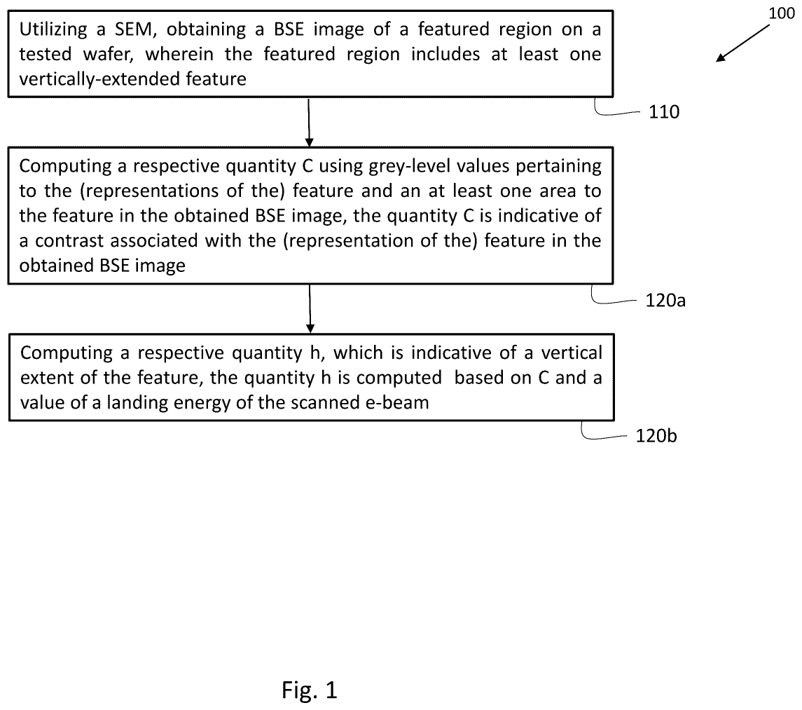

According to an aspect of some embodiments, there is provided a non-destructive method for surface metrology of patterned wafers based on measurements of backscattered electrons. FIG. 1 presents a flowchart of such a method, a method 100, according to some embodiments. Method 100 includes:

An operation 110, wherein a SEM is utilized to obtain a BSE image of a featured region on a tested wafer. The featured region includes at least one vertically-extended feature, which is (i) characterized by a BSE yield per unit depth and/or per unit volume that is substantially uniform along the vertical direction, or (ii) depressed and delimited by a material characterized by a BSE yield per unit depth or per unit volume that is substantially uniform along the vertical direction.

An operation 120, including implementing with respect to each of the at least one feature:

A suboperation 120a, wherein a respective quantity C is computed using grey-level values pertaining to the (representations of the) feature and an at least one area to the feature in the obtained BSE image. The quantity C is indicative of a contrast associated with the (representation of the) feature in the obtained BSE image.

A suboperation 120b, wherein a respective quantity h, which is indicative of a vertical extent of the feature, is computed. The quantity h is computed based on C and a value of a landing energy of the scanned e-beam.

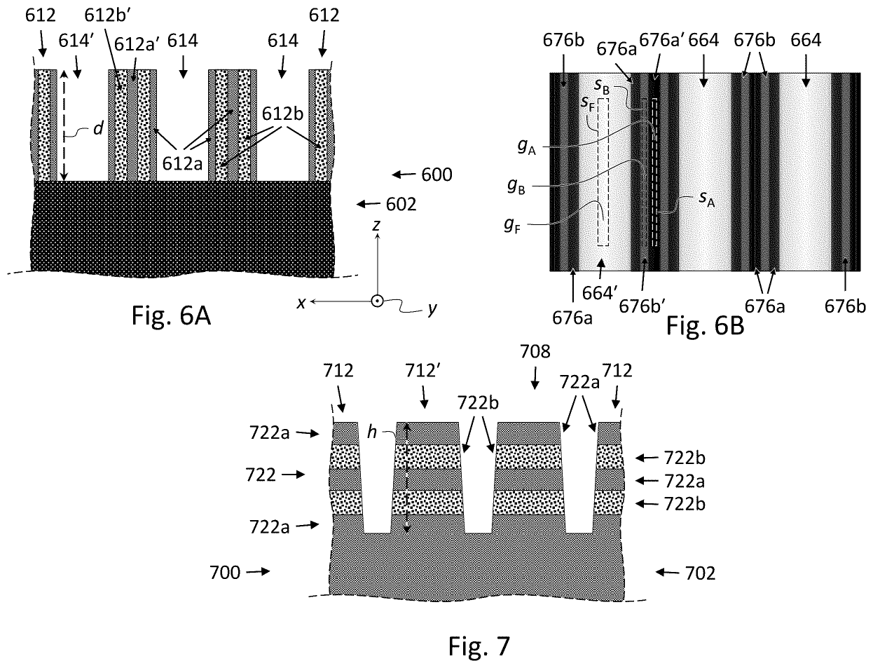

Method 100 may be implemented using a system, such as the system described below in the description of FIG. 6, or a system similar thereto. In particular, according to some embodiments, operation 110 may be implemented using a SEM configured to obtain BSE images. According to some embodiments, and as elaborated on in more detail below, in computing h, a reference BSE yield is additionally taken into account. More specifically, the reference BSE yield is used to normalize C. According to some embodiments, the reference BSE yield may correspond to an unpatterned wafer BSE yield (defined below).

As used herein, a structure (e.g. a feature, material bounding/delimiting a feature, etc.) is said to be substantially uniform in the BSE yield per unit depth or per unit volume thereof when any variations in the BSE yield therein are sufficiently small so as to allow determining the vertical extent of the feature to a required precision using method 100.

According to some embodiments, the term “substantially uniform” refers to variation of less than about 1% in the BSE yield.

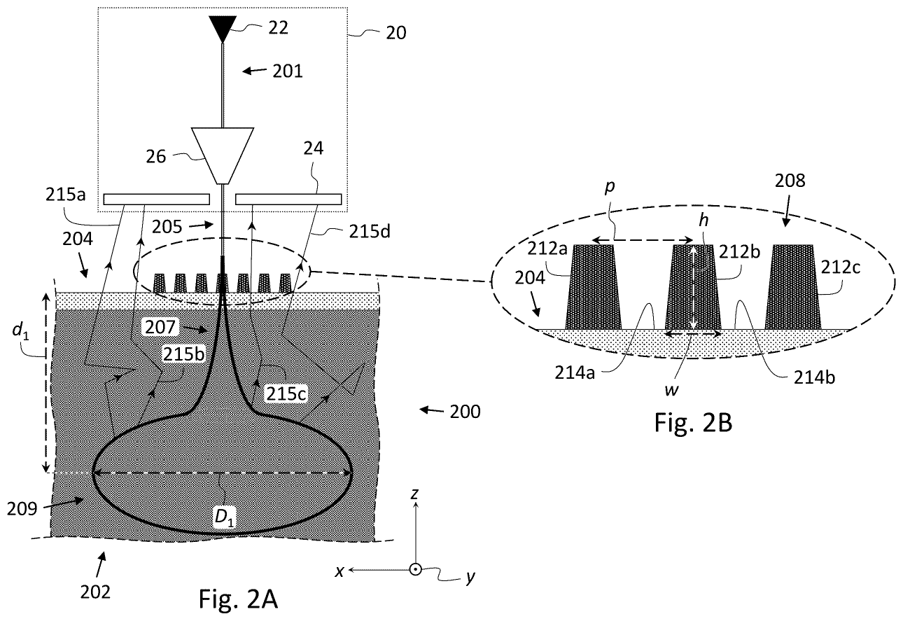

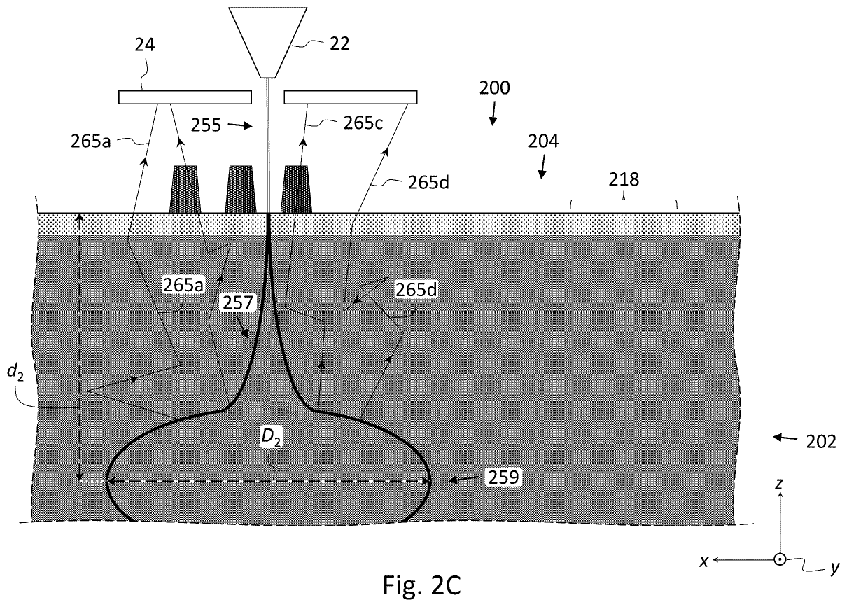

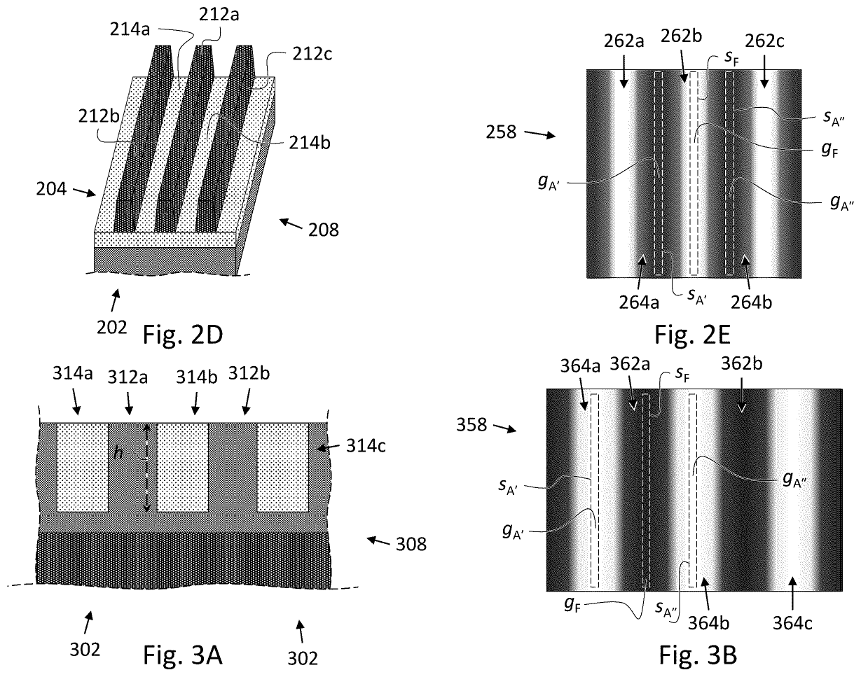

To facilitate the description of method 100 by way of a non-limiting example, reference is additionally made to FIGS. 2A-2E. FIG. 2A presents a schematic cross-sectional sideview of a (tested) wafer 200 being impinged by a first e-beam 205a produced by a SEM 20. More precisely, only a small section of wafer 200 is depicted. Wafer 200 is patterned. SEM 20 is shown delimited by a dotted line to indicate that components included therein (listed below) may be jointly maneuverable (orientable and/or translatable). Wafer 200 includes a bulk 202 (e.g. a silicon substrate) and a top layer 204 (e.g. a silicon-germanium blanket layer), which is disposed on the top of bulk 202. A featured region 208 of wafer 200 includes a plurality of vertically-extended features in the form of fins 212. Fins 212 vertically project from top layer 204 and laterally extend in parallel to one another.

FIG. 2B presents a (cross-sectional) close-up view of featured region 208, according to some embodiments. Indicated are a first fin 212a, a second fin 212b, and a third fin 212c (from fins 212). Second fin 212b is positioned between first fin 212a and third fin 212c. Also indicated are a height (i.e. vertical extent) h of a second fin 212a and a width w thereof, as well as a distance p between first fin 212a and second fin 212b. A first trench 214a extends between first fin 212a and second fin 212b. A second trench 214b extends between second fin 212b and third fin 212c. The bottom of first trench 214a constitutes an area adjacent to first fin 212a from the left. The bottom of second trench 214b constitutes an area adjacent to first fin 212a from the right. According to some embodiments, and as depicted in FIGS. 2A-2D, fins 212 nominally form a periodic pattern with a pitch (i.e. distance between adjacent fins) equal to p₀.

FIG. 2C presents a schematic cross-sectional sideview of wafer 200 being impinged by a second e-beam 255 produced by SEM 20 (e.g. the same e-beam as first e-beam 205 but offset relative thereto), according to some embodiments. FIG. 2D presents a perspective view of featured region 208, according to some embodiments. While in FIGS. 2A and 2C, first e-beam 205 and second e-beam 255, respectively, are each shown directed normally to top layer 204 (i.e. zero electronic tilt), according to some embodiments of method 100, in operation 110 the e-beams (used to acquire the BSE image) may be made to impinge to top layer 204 a small electronic tilt angle. According to some embodiments, the term “small” with regard to the electronic tilt angle may refer to up to about 0.5°, up to about 1.0°, up to about 1.2°, up to about 1.5°, up to about 2°, or up to about 4°. Impinging a tested wafer at a small electronic tilt angle may serve to reduce non-linear diffraction effects due to interference between backscattered electrons returned from the tested wafer.

Referring again to FIG. 2A, SEM 202 includes an electron gun 22, a BSE detector 24, a compound lens 26, a scanner module (not shown), and, optionally, electron optics (not shown). BSE detector 24 is configured to sense backscattered electrons returned from wafer 200. Compound lens 26 is configured to focus on wafer 200 an e-beam generated by electron gun 22. The scanner module is configured to offset the e-beam so as to enable scanning over featured region 208. The electron optics may include components, such as magnetic deflectors, configured to controllably set the projection direction of the e-beam. According to some embodiments, and as depicted in FIG. 2A, BSE detector 24 may be annular with a hole for passage therethrough of the e-beam.

Referring also to FIG. 2C, in implementing operation 110 to determine the heights of each of fins 212, SEM 20 scans featured region 208, so as to image (partially or fully) each of fins 212 and adjacent areas to each. More specifically, electron gun 22 produces an e-beam (e.g. an e-beam 201 in FIG. 2A), which is focused by compound lens 26, thereby preparing an e-beam incident on featured region 208 (e.g. first e-beam 205 in FIG. 2A, second e-beam 255 in FIG. 2C). Some of the returned electrons, i.e. sufficiently energetic electrons scattered towards BSE detector 24, are sensed by BSE detector 24. The above-described sequence of suboperations (of operation 110) may then be repeated for different offsets, so as to fully scan featured region 208.

In FIG. 2A, first e-beam 205 is shown incident on first fin 212a. More specifically, first e-beam 205 is shown striking first fin 212a on the top thereof, penetrating into first fin 212a, and crossing first fin 212a, and then top layer 204, into bulk 202. First e-beam 205 expands with the increase of the penetration thereof into wafer 200, so as to assume a shape resembling an onion. The “onion” includes a stem 207 (i.e. a stem-shaped portion of first e-beam 205) and a bulb 209 (i.e. a bulb-shaped portion of first e-beam 205). In FIG. 2A bulb 209 is shown as being fully buried within bulk 202. Substantially all (e.g. at least 80%, at least 90%, or at least 95%) of the backscattered electrons exiting wafer 200 (via top layer 204)—and, in particular, substantially all the backscattered electrons sensed by BSE detector 24—originate in backscattering events within bulk 202.

Also illustrated are trajectories 215a, 215b, 215c, and 215d of returned electrons, which are backscattered towards BSE detector 24 and sensed thereby. The trajectories are “zig-zagged” reflecting the random walk nature of electron motion within wafer 200.

The depth at which a bulb (e.g. bulb 209) is buried, and the diameter thereof, may be increased by increasing the landing energy of the e-beam. According to some embodiments, the landing energy is selected such that D₁ (the diameter of a bulb 209) is greater than the pitch p₀ of the periodic pattern by a factor of at least about 5 or at least about 10. Each possibility corresponds to separate embodiments.

As compared to FIG. 2A, wherein SEM 20 is positioned directly above first fin 212a, in FIG. 2C SEM 20 is positioned directly above second trench 214b. More specifically, second e-beam 255, which is offset with respect to first e-beam 205, is shown striking top layer 204 in second trench 214b, penetrating into top layer 204, and crossing top layer 204 into bulk 202. Second e-beam 255 projection direction may be identical to that of first e-beam 205. Also illustrated are trajectories 265a, 265b, 265c, and 265d of returned electrons, which are backscattered towards BSE detector 24 and sensed thereby.

Since bulk 202 and top layer 204 are uniform, or at least laterally (i.e. in parallel to the xy-plane) uniform, and since top layer 204 is essentially flat, second e-beam 255 penetrates deeper into bulk 202 than first e-beam 205. More precisely, being projected on first fin 212a, in order to reach bulk 202, first e-beam 205 travels through more of wafer 200 (having to pass not only through top layer 204 but also first fin 212a) as compared to second e-beam 255 (which is projected directly on top layer 204). Bulb 259 is thus buried deeper within bulk 202 than bulb 209 but may otherwise be of substantially same dimensions. Fewer electrons are returned from wafer 200 as a result of the impinging thereof with second e-beam 255 than as a result of the impinging thereof with first e-beam 205. Accordingly, and as depicted in FIG. 2E, in the obtained BSE image of featured region 208 first fin 212a appears brighter than second trench 214b (and first trench 214a).

Generally, all other things being equal, if an incident e-beam strikes a top surface of a wafer on a region that forms a depression, then fewer electrons will be returned and sensed as compared to if the region were not depressed. Similarly, all other things being equal, if an incident e-beam strikes a top surface of a wafer on an region that forms a projection (i.e. bulging upwards; e.g. a fin), then more electrons will be returned and sensed as compared to if the region were not projecting. The same applies also with respect to variances in density and material. All other things being equal, if an e-beam strikes a wafer at a first region surrounded by a second region of greater density, then fewer electrons will be returned and sensed as compared to if the first and second regions were of the same density. Similarly, all other things being equal, if an e-beam strikes a wafer at a first region surrounded by a second region of lower density, then more electrons will be returned and sensed as compared to if the first and second regions were of the same density. The present disclosure teaches how measured variations in the numbers of sensed electrons returned from a wafer due to backscattering, can advantageously be utilized to for surface metrology of wafer, and, more specifically, the vertical extent of features on the wafer.

FIG. 2E schematically illustrates a BSE image 258 of featured region 208 obtained through implementation of operation 110, according to some embodiments of method 100. Each of bands 262 in BSE image 258 depicts one of fins 212, respectively. Each of bands 264 corresponds to one of trenches 214, respectively. Since fewer electrons will be returned, and sensed by BSE detector 24, due to impinging of an e-beam on one of trenches 214, as compared to when one of fins 214 is impinged, bands 262 are brighter than bands 264. Indicated are a first band 262a, a second band 262b, and a third band 262c (from bands 262) corresponding to first fin 212a, second fin 212b, and third fin 212c, respectively. Also indicated are a fourth band 264a and a fifth band 264b (from bands 264) corresponding to first trench 214a and second trench 214b, respectively.

A stripe s_{F} extends centrally along second band 262b. A stripe s_{A′} and a stripe s_{A″} extend centrally along fourth band 264a and fifth band 264b, respectively. According to some embodiments, a grey-level value g_{F}, pertaining to second fin 212b, may be derived by averaging over some or all (grey-level values of) pixels in the stripe s_{F}. Similarly, according to some embodiments, a grey-level value g_{A′} and a grey-level value g_{A″}, pertaining to first trench 212a and second trench 212b, respectively, may be derived by averaging over some or all (grey-level values of) pixels in the stripe s_{A′} and the stripe s_{A″} respectively. To this end, according to some embodiments, image analysis software may be employed. In particular, according to some embodiments, image analysis software may be employed to recognize each of second band 262a, fourth band 264a, and fifth band 264b in BSE image 258, and, optionally, to identify and delimit a brightest stripe (e.g. stripe s_{F}) along first band 262a and darkest stripes (e.g. stripes s_{A′} and s_{A″}) along each of fourth band 264a and fifth band 264b, respectively.

According to some embodiments, the contrast associated with second fin 212b is obtained from the relation C=g_{F}−g_{A} with

$${g}_{A} = \frac{1}{2} ( {g}_{{A}^{′}} + {g}_{{A}^{″}} ) .$$

Alternatively, according to some embodiments, g_{A} may be taken to equal g_{A′} or g_{A″}. When

$${g}_{A} = \frac{1}{2} ( {g}_{{A}^{′}} + {g}_{{A}^{″}} ) ,$$

C corresponds to the average over the contrast between second band 262b and fourth band 264a and the contrast between second band 262b and fifth band 264b. When g_{A}=g_{A′}, C corresponds to the contrast between second band 262b and fourth band 264a, while, when g_{A}=g_{A″}, C corresponds to the contrast between second band 262b and fifth band 264b. According to some embodiments, in suboperation 120b h is computed based on a normalized contrast [symbol] and the value of the landing energy of the scanned e-beam. [symbol] is obtained from C through normalization by a reference BSE yield at the landing energy, or a quantity indicative thereof. As detailed below, the reference BSE yield may be quantified by a reference gray-level value g_{R}, so that [symbol] =C/g_{R}. According to some embodiments, the value of h is determined using the relation

$$h = q \cdot {C}_{𝒩} \cdot {E}^{5 / 3} , \qquad Eq . ( 1 ) .$$

E is the landing energy of the scanned e-beam (i.e. the average energy of an electron in the e-beam on striking the wafer). q is a constant essentially independent of the landing energy.

According to some embodiments, the reference BSE yield g_{R} corresponds to an unpatterned wafer BSE yield gu, which quantifies the intensity of backscattered electrons which will be returned from an unpatterned region of the tested wafer. The unpatterned region may be located near the featured region so as to minimize the effect of process variation. Accordingly, according to some embodiments, method 100 may include an additional operation, wherein an unpatterened region of the tested wafer is scanned in order to determine the unpatterned wafer BSE yield (and thereby the reference BSE yield). FIG. 2C depicts Such an unpatterned region 218 of wafer 200 is depicted in FIG. 2C. According to some embodiments of method 100, unpatterned region 218 is scanned with an e-beam at the same landing energy, as used to scan featured region 208, in order to determine the unpatterned wafer BSE yield.

Alternatively, according to some embodiments

$${g}_{R} = \frac{1}{2} ( {g}_{F} + {g}_{A} ) ,$$

or, more generally, a weighted average of g_{F} and g_{A}.

The skilled person will readily perceive that method 100 may also be applied to a featured region which is flat but contains parallelly adjacent vertically-extended features of different composition (e.g. a featured region including fins and trenches that are filled by a material different than that of the fins). FIG. 3A schematically depicts such a featured region, according to some embodiments. More specifically, FIG. 3A presents a cross-sectional sideview of a small section of tested wafer 300. Wafer 300 includes a bulk 302 (partially shown) of a first material (e.g. silicon). Bulk 302 includes parallel fins 312 and trenches 316. Trenches 316 are not empty but are each filled with a second material (e.g. oxide) that differs from the first material. A featured region 308 of wafer 302 includes fins 312 (which constitute the vertically-extended features) and narrow layers 314 of the second material separating adjacent fins 312. That is, each of narrow layers 314 fills one of fins 312, respectively. Indicated are a first fin 312a, a second fin 312b, and a third fin 312c (from features 312). Also indicated are a first narrow layer 314a and a second narrow layer 314b. First narrow layer 314a is adjacent to second fin 312b from the left and second narrow layer 314b is adjacent to second fin 312b from the right.

According to some embodiments, fins 312 and trenches 314 nominally form a periodic pattern. According to some such embodiments, in implementing method 100 to determine the height of fins 312, the landing energy is selected such the diameter of a bulb of an impinging e-beam is greater than the nominal pitch of the periodic pattern by a factor of at least about 5 or at least about 10. Each possibility corresponds to separate embodiments.

FIG. 3B schematically illustrates a BSE image 358 of featured region 308 obtained through implementation of operation 110, according to some embodiments of method 100. Each of bands 362 in BSE image 358 depicts one of fins 312, respectively. Each of bands 364 corresponds to one of narrow layer 314, respectively. Since fewer electrons will be returned (and sensed by a BSE detector utilized to image featured region 308) due to impinging of an e-beam on one of fins 312, as compared to when one of narrow layers 314 is impinged, bands 362 are darker than bands 364. Indicated are a first band 362a and a second band 362b (from bands 362) corresponding to first fin 312a and second fin 312b, respectively. Also indicated are a third band 364a, a fourth band 364b, and a fifth band 364c (from bands 364) corresponding to first narrow layer 314a, second narrow layer 314b, and third narrow layer 314c, respectively.

A stripe s_{F} extends centrally along first band 362a. A stripe s_{A′} and a stripe s_{A″} extend centrally along third band 364a and fourth band 364b, respectively. A grey-level value g_{F}, pertaining to first fin 312b, may be derived by averaging over some or all (grey-level values of) pixels in the stripe s_{F}. Similarly, a grey-level value g_{A′} and a grey-level value g_{A″}, pertaining to first trench 314a and second trench 314b, respectively, may be derived by averaging over some or all (grey-level values of) pixels in the stripe s_{A′} and the stripe s_{A″} respectively.

The heights of fins 312 may be determined in essentially the same manner as described above in the description of FIG. 2E with respect to fins 212 of wafer 200. In particular, according to some embodiments, the contrast associated with first fin 312a may be determined using the derived grey-level values g_{F}, g_{A′}, and g_{A″} in essentially the same manner as described above in the description of FIG. 2E with respect to the derivation of the contrast associated with second fin 212b.

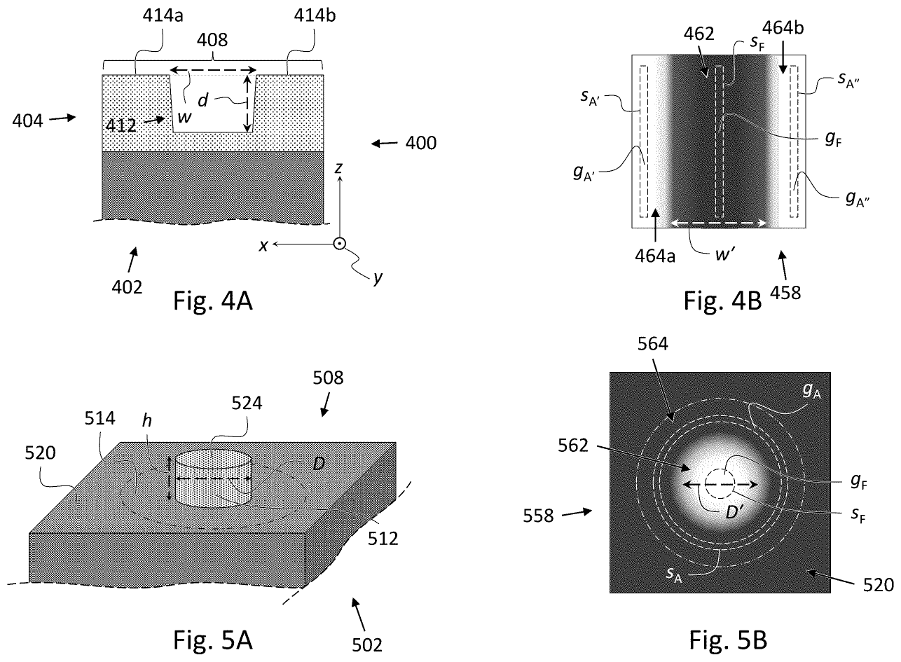

The skilled person will also readily perceive that the applicability of method 100 is not limited to featured regions characterized by a plurality vertically-projecting structures, such as fins 200. Each of FIGS. 4A and 5A schematically depicts, by way of a non-limiting example, a respective featured region including a single vertically-extended feature. Referring to FIG. 4A, a schematic cross-sectional sideview of a tested wafer 400 is presented. More precisely, only a small section of (e.g. a part of a die included in) wafer 400 is depicted. Wafer 400 includes a bulk 402 (partially shown) and a thin layer 404 disposed on bulk 402. As a non-limiting example, bulk 402 may be made of a first material (e.g. silicon) and thin layer 404 may be made of a second material (e.g. an oxide), which is of uniform density. Thin layer 404 includes a trench 412 of a depth d and a width w. Also indicated is a top surface 420 of thin layer 404. A first area 414a constitutes a strip extending along a first edge 424a of trench 412. A second area 414b constitutes a strip extending along a second edge 424n of trench 412.

A featured region 408 of wafer 402 includes trench 412 and first area 414a and second area 414b. Trench 412 constitutes a vertically-extended feature, which is depressed relative to top surface 420 and surrounded by a material of uniform composition (i.e. the second material).

According to some embodiments, in implementing method 100 to determine the depth of trench 412, the landing energy is selected such the diameter of a bulb of an impinging e-beam is greater than w (the width of trench 412) by a factor of at least about 5 or at least about 10. Each possibility corresponds to separate embodiments.

FIG. 4B schematically illustrates a BSE image 458 of featured region 408 obtained through implementation of operation 110, according to some embodiments of method 100. A band 462 in BSE image 458 depicts trench 412. Since fewer electrons will be returned (and sensed by a BSE detector utilized to image featured region 408) due to impinging of an e-beam in trench 414, as compared to when one of first area 414a and second area 414b is impinged, band 462 is brighter than the rest of BSE image 458.

A stripe s_{F} centrally extends along band 462. A stripe s_{A′} and a stripe s_{A″} extend adjacently to band 462 to the right and left thereof, respectively. A grey-level value g_{F}, pertaining to trench 412, may be derived by averaging over some or all (grey-level values of) pixels in the stripe s_{F}. Similarly, a grey-level value g_{A′} and a grey-level value g_{A″}, pertaining to first area 414a and second trench 414b, respectively, may be derived by averaging over some or all (grey-level values of) pixels in the stripe s_{A′} and the stripe s_{A″} respectively. Also indicated in FIG. 4B is a with w′ of band 462.

According to some embodiments, the contrast associated with trench 412 is obtained from the relation C=g_{F}−g_{A} with

$${g}_{A} = \frac{1}{2} ( {g}_{{A}^{′}} + {g}_{{A}^{″}} ) .$$

Alternatively, according to some embodiments, g_{A} may be taken to equal g_{A′} or g_{A″}. When

$${g}_{A} = \frac{1}{2} ( {g}_{{A}^{′}} + {g}_{{A}^{″}} ) ,$$

C corresponds to the average over the contrast between trench 412 and first band 414a and the contrast between trench 412 and second band 414b. When g_{A}=g_{A′}, C corresponds to the contrast between trench 412 and first area 414a, while, when g_{A} g_{A″}, C corresponds to the contrast between trench 412 and second area 414b.

According to some embodiments, the value of h is determined using the relation

$$h = {q}_{1} \cdot {C}_{𝒩} \cdot {E}^{5 / 3} / ( 1 - {q}_{2} \cdot w / {E}^{5 / 3} ) , \qquad Eq . ( 2 ) .$$

q₁ and q₂ are constants essentially independent of the landing energy, and w may be obtained from w′. As set forth above, w is used to denote the width of a feature. w′ is used to denote the width of a feature in a BSE and/or SE image of a featured region including the feature. Here, w is the width of trench 412 and w′ is the width of band 462. The right-hand side of Eq. (2) is seen to have the form of Eq. (1) up to the division by a correction term (which divides the numerator).

Referring to FIG. 5A, illustrated is a perspective view of a small section of a tested wafer 500, according to some embodiments. Wafer 500 includes a bulk 502 (e.g. a silicon bulk; partially shown). A projection 512 vertically projects from a top surface 520 of bulk 502. Also indicated is an area 514 of top surface 520. Area 514 surrounds projection 512 with an inner circumference of area 514 bordering projection 512. As a non-limiting example, projection 512 is shown shaped as a cylinder with a top surface 524 of the cylinder being nominally parallel to top surface 520.

A featured region 508 of wafer 500 includes projection 512 and area 514. Projection 512 constitutes a vertically-extended feature, whose base is surrounded by a material of uniform composition.

According to some embodiments, in implementing method 100 to determine the height of vertically extended feature 512, the landing energy is selected such that the diameter of a bulb of an impinging e-beam is greater than D (the diameter of projection 512) by a factor of at least about 5 or at least about 10. Each possibility corresponds to separate embodiments.

FIG. 5B schematically illustrates a BSE image 558 of featured region 508 obtained through implementation of operation 110, according to some embodiments of method 100. A spot 562 in BSE image 558 depicts projection 512. An (image) area 564 around spot 562 depicts area 514. Since more electrons will be returned (and sensed by a BSE detector utilized to image featured region 408) due to impinging of an e-beam on projection 512, as compared to when one area 514a, spot 562 appears brighter than the rest of BSE image 558.

According to some embodiments, the value of h is determined as described above in the description of FIGS. 4A and 4B, that is, using Eq. (2), with w now corresponding to d (i.e. the diameter of projection 512). d may be obtained from d′ (i.e. the diameter of spot 562) essentially as described above in the description of FIG. 4B with respect to w (i.e. the width trench 412) and w′(i.e. the width of band 462).

Additional examples of featured regions whose geometry may be characterized using method 100 are depicted in FIGS. 6A-7. Referring to FIG. 6A, a schematic cross-sectional sideview of a tested wafer 600 is presented. More precisely, only a small section of (e.g. a part of a die included in) wafer 600 is depicted. Wafer 600 includes an (e.g. silicon) bulk 602 (partially shown) from which a plurality of fins 612 vertically project. A featured region 608 of wafer 600 includes fins 612 and trenches 614. Each of trenches 614 extends between a respective pair of fins from fins 612.

Fins 612 include vertical-extending strata, which extend in parallel to the yz-plane (and in parallel to one another along). As a non-limiting example, strata are shown as including two types of strata: first strata 612a and second strata 612b. Each of first strata 612a is assumed to be of uniform composition and therefore to be characterized by a BSE yield per unit volume that is uniform along the vertical direction (i.e. defined by the z-axis). Similarly, each of second strata 612b is assumed to be of uniform composition and therefore to be characterized by a BSE yield per unit volume that is uniform along the vertical direction. First strata 612a and second strata 612b are assumed to differ in composition and may appreciably differ from one another in the respective BSE yields per unit volume thereof.

Trenches 614 constitute vertically-extended features within featured region 608. A depth of a trench 614′ from trenches 614 is indicated by d. Each of trenches 614 forms a respective depression, delimited on sides thereof by a material, which is characterized by a BSE yield per unit depth that is uniform along the vertical direction. In particular, each of trenches 614 is delimited on right and left sides thereof (as construed by a reader perusing FIG. 6A) by a respective pair of first strata 612a.

According to some embodiments, fins 612 and trenches 614 nominally form a periodic pattern. According to some such embodiments, in implementing method 100 to determine the depth of trenches 614, the landing energy is selected such the diameter of a bulb of an impinging e-beam is greater than the nominal pitch of the periodic pattern by a factor of at least about 5 or at least about 10. Each possibility corresponds to separate embodiments.

FIG. 6B schematically illustrates a BSE image 658 of featured region 608 obtained through implementation of operation 110, according to some embodiments of method 100. Each of bands 664 depicts the bottom of a respective one of trenches 614, respectively. Each of bands 676a depicts the top of a respective one of strata 612a, respectively. Each of bands 676b depicts the top of a respective one of strips 612b, respectively. Since fewer electrons will be returned (and sensed by a BSE detector utilized to image featured region 608) due to impinging of an e-beam on one of fins 612, as compared to when one bulk 602 is directly impinged (i.e. when the e-beam is projected into one of trenches 614), both bands 676a and bands 676b are darker than bands 664. As a non-limiting example intended to facilitate the description, it is assumed that the BSE yield per unit volume of first strata 612a is smaller than that of second strata 612b. Accordingly, in FIG. 6B bands 676a are depicted as darker than bands 676b.

A stripe s_{F} extends centrally along a band 664′. A stripe s_{A} and a stripe s_{B} extend centrally along a band 676a′ and a band 676b′, respectively. A grey-level value g_{F}, pertaining to a trench 614′ (from trenches 614), may be derived by averaging over some or all (grey-level values of) pixels in the stripe s_{F}. Similarly, a grey-level value g_{A} and a grey-level value g_{B}, pertaining to a stratum 626a′ (from first strata 626a) and a stratum 626b′ (from second strata 626b), respectively, may be derived by averaging over some or all (grey-level values of) pixels in the stripe s_{A} and the stripe s_{B}, respectively.

The depth d of trench 614′ may be determined from Eq. (1) in a similar manner to that described in the description of FIG. 2E with respect to fins 212 of wafer 200. More specifically, two sets of different contrasts associated with trench 614′ may be computed. As used herein, the term set covers not only multi-element sets but also single element sets. In embodiments wherein the materials making up firsts strata 612a and second strata 612b, respectively, sufficiently differ in the BSE yields per unit volume thereof, the value of q plugged into Eq. (1) will generally depend on whether the computed contrast has been computed with respect to one or more of first bands 676a or one or more of second bands 676b. For example, the contrast C_{A}=g_{F}−g_{A} between band 664′ and stratum 676a′ may be used to compute the depth d of trench 614′, as described above in the description of FIG. 2E, using a first value of q: q=q_{A}. Similarly, the contrast C_{B}=g_{F}−g_{B} between band 664′ and stratum 676a′ may be used to compute the depth d of trench 614′, as described above in the description of FIG. 2E, using a second value of q: q=q_{B}≠q_{A}. According to some embodiments, both first bands 676a and second bands 676b may be used to compute the depth d, for instance, by averaging over the two values of d obtained using C_{A} and q_{A}, and C_{B} and q_{B}, respectively.

Referring to FIG. 7, a schematic cross-sectional sideview of a (tested) wafer 700 is presented. More precisely, only a small section of (e.g. a part of a die included in) wafer 700 is depicted. Wafer 700 includes an (e.g. silicon) bulk 702 (partially shown) from which a plurality of fins 712 vertically project. A featured region 708 of wafer 700 includes fins 712. Also indicated are trenches 714. Each of trenches 714 extends between a respective pair of fins from fins 712.

Each of fins 712 includes laterally-extending layers 722, which are disposed one on top of the other. As a non-limiting example, layers 722 are shown as including two types of layers: first layers 722a and second layers 722b. According to some embodiments, and as depicted in FIG. 7, first layers 722a may be composed of the same material as bulk 702.

First layers 722a and second layers 722b are assumed to differ in composition (e.g. to be composed of different materials) but nevertheless to vary little from one another in the respective BSE yields per unit volume thereof. More specifically, the difference in the BSE yields per unit volume between first layers 722a and second layers 722a is assumed to be sufficiently small so as to allow determining a height of fins 712 to a required precision using method 100. A height of a fin 712′ from fins 712 is indicated by h. It is in this sense that fins 712 are said to be characterized by a BSE yield per unit volume that is substantially uniform.

According to some embodiments, fins 712 and trenches 714 nominally form a periodic pattern. According to some such embodiments, in implementing method 100 to determine the height of fins 714, the landing energy is selected such the diameter of a bulb of an impinging e-beam is greater than the nominal pitch of the periodic pattern by a factor of at least about 5 or at least about 10. Each possibility corresponds to separate embodiments. Given a BSE image of featured region 708—obtained as prescribed by operation 110—the height of fins 712 may be determined in essentially the same way as described above with respect to fins 212 of wafer 200 in the description of FIG. 2E.

### Systems

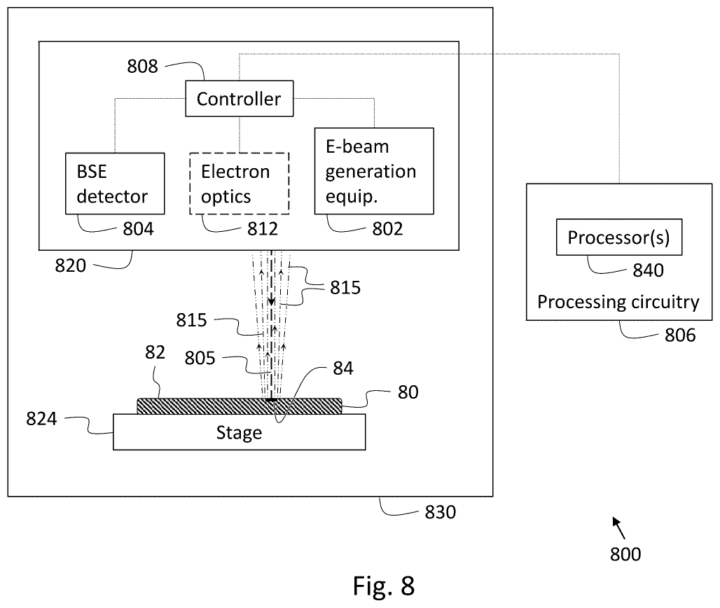

According to an aspect of some embodiments, there is provided a computerized system for surface metrology of patterned wafers based on BSE imaging. FIG. 8 schematically depicts such a system, a system 800, according to some embodiments. As will be apparent from the description thereof, system 800 may be used to implement method 100.

System 800 includes e-beam generation equipment 802, a BSE detector 804 (such as BSE detector 24), processing circuitry 806, and a controller 808. According to some embodiments, system 800 may further include electron optics 812 configured to direct and/or focus an e-beam generated by e-beam generation equipment 802, and/or direct electrons (e.g. onto BSE detector 804) scattered from a wafer due to the irradiation thereof with the e-beam. According to some embodiments, and as depicted in FIG. 8, e-beam generation equipment 802, BSE detector 804, electron optics 812, and controller 808 may constitute components of a SEM 820. Alternatively, according to some embodiments, controller 808 may be included in processing circuitry 806. According to some embodiments, system 800 may further include a stage 824 configured to accommodate a (tested) wafer 80, such as, for example, any one of wafers 200, 300, 400, 500, 600, and 700.

Dotted lines between elements indicate functional or communicational association between the elements.

An incident e-beam 805 (indicated by a dashed line), generated by e-beam generation equipment 802, is shown impinging on a top surface 82 wafer 80 on a featured region 84 thereof. As a result of the impinging of incident e-beam 805 on wafer 80, and the penetration of incident e-beam 805 into wafer 80, backscattered electrons are returned from wafer 80. Arrows 815 indicate trajectories of backscattered electrons, which are backscattered from wafer 80 in the direction of BSE detector 804.

According to some embodiments, e-beam generation equipment 802 may be configured to allow controllably setting an orientation and/or an offset of an e-beam projected thereby, and scan the e-beam on a on a controllably selectable region of a wafer (e.g. wafer 80). According to some embodiments, e-beam generation equipment 802 may be configured to prepare the e-beam so as to impinge on a tested wafer (e.g. wafer 80) at a small electronic tilt angle in order to minimize, or at least reduce, non-linear diffraction effects due to interference between backscattered electrons returned from the tested wafer. According to some embodiments, the incidence angle may be up to up to about 0.5°, up to about 1.0°, up to about 1.2°, up to about 1.5°, up to about 2°, or up to about 4°. According to some embodiments, e-beam generation equipment 802 may be configured to controllably set the azimuth angle at which the e-beam impinges on the wafer.

E-beam generation equipment 802 may include an electron gun (not shown), such as electron gun 22, a scanner module (such as the scanner module of SEM 20; not shown), and a compound lens (not shown), such as compound lens 26. According to some such embodiments, the electron gun may be orientable and/or translatable. According to some embodiments, e-beam generation equipment 802 may include a plurality of electron guns, each configured to project an e-beam at a respective orientation (or range of orientations) and/or offset. According to some embodiments, each of the electron guns may be mechanically orientable and/or translatable.

Additionally, or alternatively, according to some embodiments, stage 824 is (i) translatable, so as to allow controllably setting an offset of an e-beam impinging thereon, and/or (ii) orientable and rotatable, so as to allow controllably setting a projection direction of the impinging e-beam relative to the wafer.

According to some embodiments, electron optics 812 may include an electrostatic lens(es) and a magnetic deflector(s), which may be used to guide and manipulate an e-beam generated by e-beam generation equipment 802, and thereby controllably set a projection direction and/or an offset of the generated e-beam.

BSE detector 804 is configured to sense backscattered electrons returned from wafer 80. BSE detector 804 is further configured to relay (optionally, via controller 808) the data collected thereby (e.g. the measured intensities of electrons incident on BSE detector 804) to processing circuitry 806.

According to some embodiments, electron optics 812 may include an electrostatic lens(es) and a magnetic deflector(s), which may be used to guide onto BSE detector 804 backscattered electrons generated due to the penetration into wafer 80 of an e-beam generated by e-beam generation equipment 802.

According to some embodiments, BSE detector 804 may be a large-area BSE detector including a plurality of independently and individually actuatable (i.e. on/off switchable) segments. Each of the segments may be positioned so as to sense backscattered electrons returned at a respective return angle, thereby allowing to selectively sense backscattered electrons returned from wafer 80 at any one of a plurality of return angles. Additionally, or alternatively, according to some embodiments, BSE detector 804 is laterally and/or vertically translatable, thereby allowing to control the collection angle (i.e. sense backscattered electrons returned from wafer 80 at a desired return angle).

According to some embodiments, SEM 820 and stage 824 may be housed within a vacuum chamber 830.

Controller 808 may be functionally associated with e-beam generation equipment 802 and, optionally, stage 824. More specifically, controller 808 is configured to control and synchronize operations and functions of the above-listed equipment, tools, and components during profiling of a tested wafer. In particular, controller 808 may be configured to instruct e-beam generation equipment 802 and/or stage 824 to change the striking location of incident e-beam 805 on featured region 84 (or, what is the same thing, the offset of incident e-beam 805) or shift a line along which e-beam 805 is scanned.

Processing circuitry 806 includes one or more processors (i.e. processor(s) 840), and, optionally, RAM and/or non-volatile memory components; not shown). The one or more processors are configured to execute software instructions stored in the non-volatile memory components. Through the execution of the software instructions, a BSE image (e.g. obtained by BSE detector 804) of a featured region (e.g. featured region 84) on a tested wafer (e.g. wafer 80) is processed to determine the vertical extents of one or more features included in the featured region, essentially as described above in the description of FIGS. 1-7.

According to some embodiments, processor(s) 844 may include at least one graphics processing unit (GPU). The at least one GPU may be configured to: (i) identify in a raw or processed BSE image of a featured region (e.g. BSE image 258 of featured region 208) a first image area (e.g. second band 262b) corresponding to a (e.g. a vertically-extended) feature (e.g. second fin 212b), (ii) determine the contrast between the first image area and one or more other image areas (e.g. fourth band 264a and fifth band 264b) adjacent to the first image area, and, optionally, (iii) determine the width of the of the first image area. According to some embodiments, the at least one GPU may be configured to process a raw BSE image so as to remove noise, crop the BSE image, and/or enhance contrast.

### Experimental Results

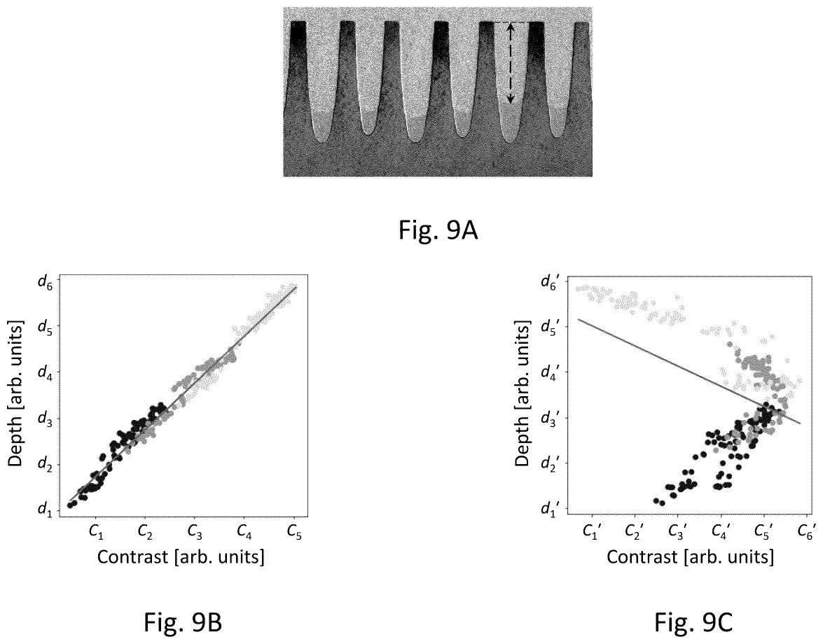

FIG. 9A presents a transmission electron microscopy image of a silicon structure 900. The silicon structure includes a plurality of fins 914 with amorphous shallow trench isolation (STI) layers there between. A depth of trench 914′ is indicated by a double-headed arrow d. The depth d measures the difference in height between the top of the two fins adjacent to trench 914′ and the top of the STI layer within trench 914′.

FIG. 9B presents results obtained employing method 100, according to some embodiments thereof, in order to estimate the depth of trenches in three different wafers, including silicon structures such as silicon structure 900. The horizontal axis signifies the contrast (in arbitrary units) and the vertical axis the depth of the trench (in arbitrary units). The graduations on each of the horizontal and vertical axes are linearly spaced-apart with Cᵢ<Cᵢ₊₁ and dₖ<dₖ₊ᵢ. Each point corresponds to a depth, which was deduced according to Eq. (1) based on a measured contrast (obtained in accordance with method 100) associated with a respective trench. Crucially, and as elaborated on below, the impinging e-beam was directed on the wafers at a small (but not zero) electronic tilt angle. The purple, yellow, and green points pertain to the first, second, and third wafer. respectively. The contrast is seen to be proportional to the depth, in accordance with Eq. (1).

FIG. 9C differs from FIG. 9B in presenting results obtained by impinging the e-beams on the wafers at a zero electronic tilt angle. As can be seen, the contrast is no longer proportional to the depth, implying the unreliability of the obtained results and the criticality (in this case) of impinging at a non-zero electronic tilt angle. Without being bound by any theory, the non-linear response is caused by diffraction.

In the description and claims of the application, the words “include” and “have”, and forms thereof, are not limited to members in a list with which the words may be associated.

As used herein, the term “about” may be used to specify a value of a quantity or parameter (e.g. the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

According to some embodiments, an estimated quantity or estimated parameter may be said to be “about optimized” or “about optimal” when falling within 5%, 10% or even 20% of the optimal value thereof. Each possibility corresponds to separate embodiments. In particular, the expressions “about optimized” and “about optimal” also cover the case wherein the estimated quantity or estimated parameter is equal to the optimal value of the quantity or the parameter. The optimal value may in principle be obtainable using mathematical optimization software. Thus, for example, an estimated (e.g. an estimated residual) may be said to be “about minimized” or “about minimal/minimum”, when the value thereof is no greater than 101%, 105%, 110%, or 120% (or some other pre-defined threshold percentage) of the optimal value of the quantity. Each possibility corresponds to separate embodiments.

For ease of description, in some of the figures a three-dimensional cartesian coordinate system (with orthogonal axes x, y, and z) is introduced. It is noted that the orientation of the coordinate system relative to a depicted object may vary from one figure to another. Further, the symbol ⊙ may be used to represent an axis pointing “out of the page”, while the symbol ⊗ may be used to represent an axis pointing “into the page”.

Referring to the figures, in block diagrams and flowcharts, optional elements and operations, respectively, may appear within boxes delineated by a dashed line. Further, in block diagrams, dotted lines connecting elements may be used to represent functional association or at least one-way or two-way communicational association between the connected elements.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although operations of methods, according to some embodiments, may be described in a specific sequence, the methods of the disclosure may include some or all of the described operations carried out in a different order. In particular, it is to be understood that the order of operations and suboperations of any of the described methods may be reordered unless the context clearly dictates otherwise, for example, when a latter operation requires as input the output of earlier operation or when a latter operation requires the product of an earlier operation. A method of the disclosure may include a few of the operations described or all of the operations described. No particular operation in a disclosed method is to be considered an essential operation of that method, unless explicitly specified as such.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purposes and should not be regarded as limiting. Citation or identification of any reference in this application shall not be construed as an admission that such reference is available as prior art to the disclosure. Section headings are used herein to ease understanding of the specification and should not be construed as necessarily limiting.

What is claimed is:

1. A non-destructive method for determining a vertical extent of a feature of a patterned wafer, the method comprising:
using a scanning electron microscope (SEM) to scan an e-beam over a featured region on a tested wafer and sense backscattered electrons returned from the tested wafer to obtain a backscattered electron (BSE) image of the featured region, wherein the featured region comprises at least one vertically-extended feature, which is (i) characterized by a BSE yield per unit volume that is substantially uniform along the vertical direction and/or (ii) depressed and delimited on sides thereof by a material characterized by a BSE yield per unit depth and/or unit volume that is substantially uniform along the vertical direction, wherein the scanned e-beam is projected on the tested wafer so as to impinge thereon at an electronic tilt angle of up to 2° in order to minimize non-linear diffraction effects; and
for each of the at least one vertically-extended feature:
computing a respective quantity C indicative of a contrast associated with the feature in the obtained BSE image using grey-level values pertaining to the feature and at least one adjacent area to the feature; and
computing a respective quantity h, which is indicative of a vertical extent of the feature, based on C and a value of a landing energy of the scanned e-beam.

2. The method of claim 1, wherein h is computed based on a normalized contrast [symbol] and the value of the landing energy of the scanned e-beam, wherein [symbol] is obtained from C through normalization by a reference BSE yield at the landing energy, or a quantity indicative thereof.

3. The method of claim 1, wherein the reference BSE yield is an unpatterned wafer BSE yield corresponding to an intensity of backscattered electrons, which would be returned from an unpatterned region of the tested wafer near the featured region.

4. The method of claim 1, wherein C is the contrast associated with the feature in the obtained BSE image and/or wherein h is the vertical extent of the feature.

5. The method of claim 1, wherein the at least one vertically-extended feature comprises a plurality of features, the features are of a same intended design and are nominally arranged in a periodic array.

6. The method of claim 1, wherein the landing energy is selected such that a diameter of a bulb-shaped interaction region, which is formed by the scanned e-beam within the tested wafer and wherefrom substantially all of the sensed backscattered electrons are returned, is greater than a pitch, or each of the pitches, of the periodic array by a factor of at least about 10.

7. The method of claim 1, wherein the landing energy is selected such that a diameter of a bulb-shaped interaction region, which is formed by the scanned e-beam within the tested wafer and wherefrom substantially all of the sensed backscattered electrons are returned, is greater than the vertical extent of the feature by a factor of at least about 10.

8. The method of claim 1, wherein the landing energy is selected such that the scanned e-beam penetrates the tested wafer to a depth which is greater than the vertical extent of the feature by a factor of at least about 10.

9. The method of claim 1, wherein the scanned e-beam is projected on the tested wafer so as to impinge thereon about perpendicularly thereto.

10. The method of claim 1, wherein the scanned e-beam is projected on the tested wafer so as to impinge thereon at an electronic tilt angle of about 1-2° in order to minimize non-linear diffraction effects.

11. The method of claim 1, wherein the landing energy is selected such that a diameter of a bulb-shaped interaction region, which is formed by the scanned e-beam within the bulk and wherefrom substantially all of the sensed backscattered electrons are returned, is greater by a factor of at least about 10 than periodicity lengths characterizing the bulk and any periodic layers disposed thereon.

12. The method of claim 1, further comprising estimating the reference BSE yield of the tested wafer by measuring an intensity of backscattered electrons returned from an unpatterned wafer of a same design intent as the bulk of the tested wafer.

13. The method of claim 1, wherein the tested wafer is constituted by an unfinished wafer in one of intermediate stages of fabrication thereof following the patterning.

14. The method of claim 1, wherein the at least one vertically-extended feature is constituted by a fin or a trench of a gate all around (GAA) transistor or a fin field effect transistor (FinFET), in a non-final fabrication stage thereof.

15. The method of claim 1, wherein the landing energy is between about 10 keV and about 100 keV.

16. The method of claim 1, wherein the at least one vertically-extended feature is constituted by a fin, the at least one adjacent area is constituted by at least one trench, respectively, which is adjacent to the fin.

17. The method of claim 1, wherein the tested wafer comprises a plurality of vertically-extended features;
wherein using the SEM is implemented with respect to each of the plurality of vertically-extended features; and
wherein C corresponds to an average contrast associated with the plurality of vertically-extended features in the obtained BSE images and is computed using grey-level values pertaining to each of the features in each of the obtained BSE images, and/or wherein h corresponds to an average vertical extent of the features and is computed using at least C and/or the grey-level values pertaining to each of the features in each of the obtained BSE images, as well as the value of the landing energy of the scanned e-beam and a reference BSE yield at the landing energy or a quantity indicative thereof.
